(19) United States
(12) Patent Application Publication
(10) Pub. No.: US 2022/0181119 A1
(43) Pub. Date: Jun. 9, 2022

(54) SUBSTRATE PROCESSING APPARATUS

(71) Applicant: Jusung Engineering Co., Ltd., Gwangju-si (KR)

(72) Inventor: Bu-Il JEON, Gwangju-si (KR)

(21) Appl. No.: 17/677,067

(22) Filed: Feb. 22, 2022

Related U.S. Application Data
(63) Continuation of application No. PCT/KR2020/013310, filed on Sep. 20, 2020.

(30) Foreign Application Priority Data
Oct. 10, 2019 (KR) 10-2019-0125478

(51) Int. Cl. H01J 37/32

(52) U.S. Cl. CPC H01J 37/32174; H01J 37/3244; H01J 37/32091; H01J 37/32532

(57) ABSTRACT

A substrate processing apparatus includes a process chamber, an upper electrode disposed in an upper portion inside the process chamber and disposed to be spaced apart from an upper surface of the process chamber, a lower electrode disposed to oppose the upper electrode at a constant distance from the upper electrode, a substrate seating means, electrically grounded and disposed to face the lower electrode at a constant distance from the lower electrode, in which a substrate is mounted, and a variable capacitor connected between the lower electrode and a ground or between the lower electrode and an output terminal of an RF power supply.

### CROSS-REFERENCE TO RELATED APPLICATIONS

This application is a continuation of and claims priority to PCT/KR2020/013310 filed on Sep. 29, 2020, which claims priority to Korea Patent Application No. 10-2019-0125478 filed on Oct. 10, 2019, the entireties of which are both hereby incorporated by reference.

### TECHNICAL FIELD

The present disclosure relates to a substrate processing apparatus and, more particularly, to a substrate processing apparatus in which RF power is divided from a single RF power supply to generate first plasma and second plasma in different regions.

### BACKGROUND

A substrate processing apparatus according to the prior art includes a substrate seating means, operating as an electrode supporting a substrate, and an upper electrode vertically spaced apart from the substrate seating means to face the substrate seating means. When RF power is applied to the upper electrode, inductively coupled plasma is generated between the upper electrode and the substrate seating means. A substrate disposed on the substrate seating means is plasma-treated. The plasma may decompose a reactive gas to deposit a thin film on the substrate. The upper electrode operates a gas supply unit, and a mixed gas including a plurality of gases provided from the upper electrode is ejected through a plurality of nozzles formed in a lower surface of the upper electrode. Accordingly, the plurality of nozzles may uniformly inject a gas into a large-area substrate. The upper electrode serves as both an injection structure and an electrode. A shape of a surface of the upper electrode and a shape of the nozzle are adjusted to provide a large-area film quality and film forming uniformity control effect. However, bulk plasma generated between the upper electrode and the substrate seating means is limited in controlling large-area film quality and film forming uniformity due to diffusion characteristics.

With the recent increasing demand for large-area flat panel displays (FPDs), high-quality organic film formation is required. In addition, there is an emerging need for atomic layer deposition (ALD), in which a thin film is formed by alternately injecting two types of gas, in a large-area encapsulation process or an oxide semiconductor deposition process.

### SUMMARY

Example embodiments of the present disclosure is to provide a substrate processing apparatus in which RF power is divided between an upper electrode and a lower electrode stacked on each other to generate first plasma and second plasma in different regions, respectively. The substrate processing apparatus may be a parallel plate capacitively coupled plasma apparatus including an upper electrode having a protrusion portion, a lower electrode having an opening aligned with the protrusion portion, and a grounded substrate seating means. A first gas is supplied to the substrate through a first gas path formed in the upper electrode, and the first plasma is generated between the protrusion portion of the upper electrode and the substrate seating means. In addition, a second gas is supplied to the substrate through a second gas path between the upper electrode and the lower electrode, and the second plasma is generated between the lower electrode and the substrate seating means. The first plasma and the second plasma may be generated by dividing power and receiving the divided power from a single RF power supply. A division ratio of power, generating the first plasma and the second plasma, may be achieved by adjusting capacitance of a variable capacitor connected between the lower electrode and a ground or between the upper electrode, and an output terminal of the RF power supply and the lower electrode.

Example embodiments of the present disclosure provide a substrate processing apparatus in which RF power is arbitrarily divided to each of an upper electrode and a lower electrode to perform plasma enhanced atomic layer deposition.

A substrate processing apparatus according to an example embodiment includes a process chamber, an upper electrode having a plurality of protrusion portions spaced apart from an upper surface of an upper portion of the process chamber to protrude downwardly, a lower electrode disposed below the upper electrode, a substrate seating means, electrically grounded and disposed to face the lower electrode, on which a substrate is mounted, and a variable capacitor connected between the lower electrode and a ground or between the lower electrode and an RF power supply.

In an example embodiment, the upper electrode may be connected to the RF power supply to generate a first plasma between the protrusion portion and the substrate seating means, and RF power of the RF power supply may generate a second plasma between the lower electrode and the substrate seating means.

In an example embodiment, a first gas may be supplied to the substrate seating means through a first nozzle formed in the protrusion portion, and a second gas may be supplied to the substrate seating means through a second nozzle, formed in a lower surface of the upper electrode, through an opening.

In an example embodiment, the protrusion portions and a plurality of first nozzles may be periodically disposed in a matrix form, and a plurality of second nozzles may be spaced apart from the first nozzles to be periodically disposed in a matrix form.

In an example embodiment, the substrate processing apparatus may further include a reactive element connected between the upper electrode and the lower electrode.

In an example embodiment, an output terminal of the RF power supply may be connected to the upper electrode, RF power of the RF power supply may be transferred to the lower electrode through a parasitic capacitor between the upper electrode and the lower electrode, and the variable capacitor may be connected between the lower electrode and a ground.

In an example embodiment, an output terminal of the RF power supply may be connected to the upper electrode, the variable capacitor may be connected between the upper electrode and the lower electrode, and RF power of the RF power supply may be transferred to the lower electrode through the variable capacitor and a parasitic capacitor between the upper electrode and the lower electrode.

In an example embodiment, the substrate processing apparatus may further include a fixed inductor connected between the upper electrode and the lower electrode.

A substrate processing apparatus according to an example embodiment includes an upper electrode disposed in an upper portion of a process chamber and disposed to be spaced apart from an upper surface of the process chamber, a lower electrode disposed below the upper electrode at a constant distance from the upper electrode and disposed to oppose the upper electrode, a substrate seating means, electrically ground, disposed below the lower electrode at a constant distance from the upper electrode, and disposed to face the lower electrode, on which a substrate is mounted, and a variable capacitor connected between the lower electrode and a ground or between the lower electrode and an output terminal of an RF power supply. The upper electrode has a plurality of protrusion portions protruding in a direction of the lower electrode, and the plurality of protrusion portions are respectively aligned with openings formed in the lower electrode. A method of operating the substrate processing apparatus includes supplying a first gas to the substrate seating means trough a first nozzle formed in the protrusion portions, supplying a second gas to the substrate seating means through a second nozzle, formed in a lower surface of the lower electrode, through the openings, supplying RF power to the upper electrode by the RF power supply to generate first plasma between the protrusion portions and the substrate seating means, and dividing the RF power, supplied to the upper electrode, to the lower electrode by the RF power supply to generate second plasma between the lower electrode and the substrate seating means.

In an example embodiment, the first plasma and the second plasma may be simultaneously generated.

In an example embodiment, the method may further include changing capacitance of the variable capacitor.

A substrate processing apparatus according to an example embodiment includes a process chamber, an upper electrode disposed inside the process chamber and having a nozzle protruding in a lower length direction, a lower electrode disposed below the upper electrode, and a substrate seating means, disposed to face the lower electrode, on which a substrate is mounted.

The lower electrode is electrically floated.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1 is a plan view of a substrate processing apparatus according to an example embodiment of the present disclosure.

FIG. 2 is a cross-sectional view taken along line A-A′ line in FIG. 1.

FIG. 3 is a cross-sectional view taken along line B-B′ in FIG. 1.

FIG. 4 is a cross-sectional view taken along line C-C′ in FIG. 1.

FIG. 5 is a cutaway perspective view taken along line D-D′ in FIG. 1.

FIG. 6 is a circuit diagram illustrating the substrate processing apparatus in FIG. 1.

FIG. 7 is a conceptual diagram illustrating a substrate processing apparatus according to another example embodiment of the present disclosure.

FIG. 8 is a circuit diagram illustrating the substrate processing apparatus in FIG. 7.

FIG. 9 is a cutaway perspective view illustrating a substrate processing apparatus according to another example embodiment of the present disclosure.

FIG. 10 is a circuit diagram illustrating the substrate processing apparatus in FIG. 9.

FIG. 11 is an exploded cutaway perspective view illustrating a substrate processing apparatus according to another example embodiment of the present disclosure.

FIG. 12 is a cutaway perspective view illustrating a substrate processing apparatus according to another example embodiment of the present disclosure.

FIG. 13 is a circuit diagram of the substrate processing apparatus in FIG. 12.

### DETAILED DESCRIPTION

With the recent increasing demand for large-area flat panel displays, formation of a high-quality organic layer is required. In particular, a need for atomic layer deposition, in which two types of gas are alternately injected to form a thin film, is emerging in a large-area encapsulation process or an oxide semiconductor deposition process.

In a substrate processing apparatus according to an example embodiment, a first plasma generation space, in which a reactive gas is sufficiently activated and first plasma is generated, and a second plasma generation space, in which excessive plasma exposure to a thin film is suppressed, may be distinguished from each other. In addition, a ratio of power generating the first plasma to power generating second plasma may be adjusted by using a variable capacitor.

According to an example embodiment, a substrate processing apparatus may include a substrate seating means and a gas injection unit disposed to be spaced apart from each other. The gas injection unit includes an upper electrode and a lower electrode stacked and spaced apart from each other. The upper electrode having a protrusion portion and the lower electrode having an opening aligned with the protrusion portion receive divided RF power from a single RF power supply through a parasitic capacitor and a variable capacitor. In addition, the gas injection unit supplies a first gas and a second gas to a substrate through different paths.

According to an example embodiment, an output of an RF power supply may be supplied to the upper electrode after branching off, and a portion of RF power supplied to the upper electrode may be transferred to the lower electrode through a parasitic capacitor between the upper electrode and the lower electrode. First RF power, supplied between the upper electrode and a substrate seating means, and second RF power, supplied between the lower electrode and the substrate seating means, may be independently controlled. To this end, a variable capacitor is connected between the lower electrode and the ground. In this case, a portion of the RF power, applied to the upper electrode, generate first plasma between the upper electrode and the substrate seating means opposing each other through an opening of the lower electrode. The rest of the RF power is transferred to the lower electrode through the parasitic capacitor, and second plasma is generated between the lower electrode and the substrate seating means. When capacitance of the variable capacitor is adjusted, a division ratio of the first RF power to the second RF power may be adjusted. The power division ratio may be adjusted to suppress excessive exposure of the second plasma to a thin film at low plasma density while sufficiently activating a reactive gas at high plasma density. The RF power is transferred to the lower electrode through the parasitic capacitor between the upper electrode and the lower electrode.

One end of the variable capacitor may be connected to the lower electrode, and the other end of the variable capacitor may be connected to a ground. When the RF power is applied to the upper electrode, first current flows between the upper electrode and the ground, and second current is allowed to flow to the lower electrode by the parasitic capacitor between the lower electrode and the upper electrode.

According to the present disclosure, characteristics of a deposited thin film may be improved. When capacitance of the variable capacitor is adjusted, the first plasma may have a higher electron temperature and higher plasma density than the second plasma. The first plasma may provide a high dissociation rate of the reactive gas.

According to an example embodiment, an upper electrode of a substrate processing apparatus may simultaneously or sequentially supply two types of gas (a precursor gas and a reactive gas) to a substrate through different paths for an atomic layer deposition process. For example, the upper electrode may be multiplexed to supply the two types of gases through the different paths.

In the plasma substrate processing apparatus according to an example embodiment, different plasma densities may be provided for each region to form a high-quality thin film in an atomic layer deposition process using a precursor gas and a reactive gas.

Hereinafter, the present disclosure will be described in more detail based on preferred embodiments. However, these embodiments are for better understanding of the present disclosure, and it is obvious to those skilled in the art that the scope of the present disclosure is not limited thereto. In addition, in the case in which detailed description of known functions or configurations in relation to the present disclosure is judged as unnecessarily making the essence of the present disclosure vague, the detailed description will be excluded.

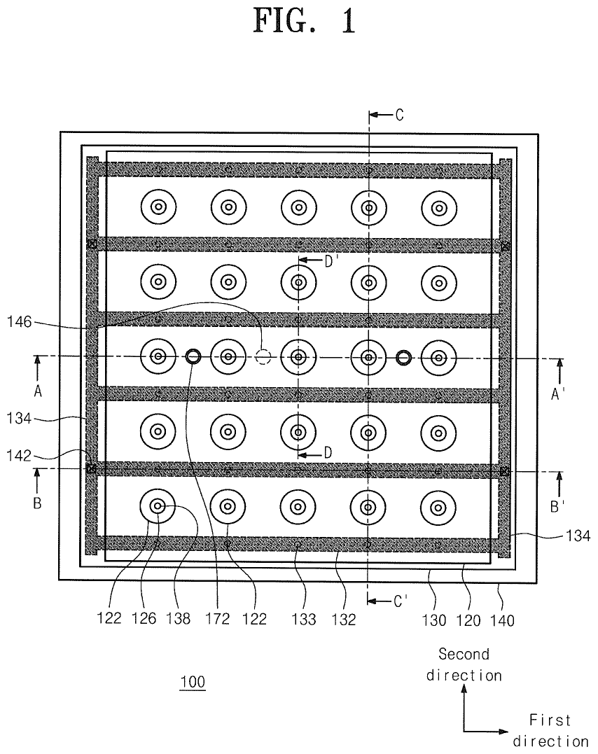

FIG. 1 is a plan view of a substrate processing apparatus according to an example embodiment of the present disclosure.

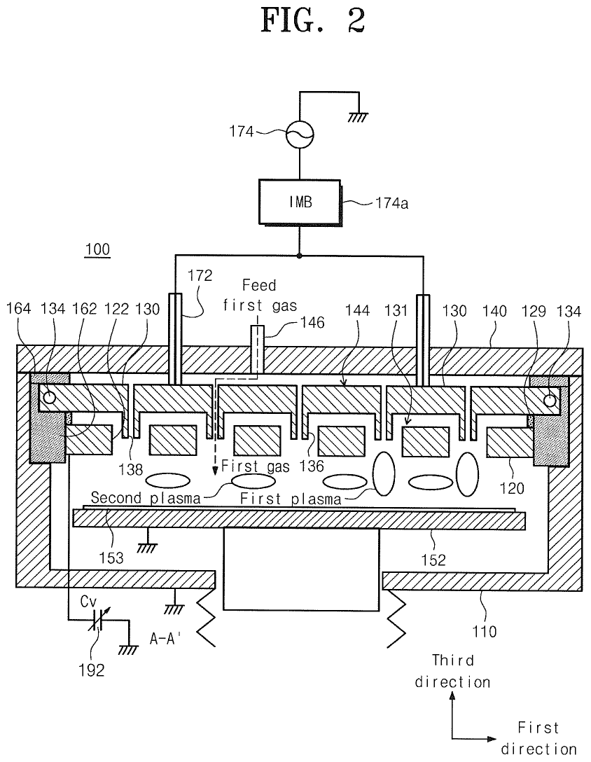

FIG. 2 is a cross-sectional view taken along line A-A′ line in FIG. 1.

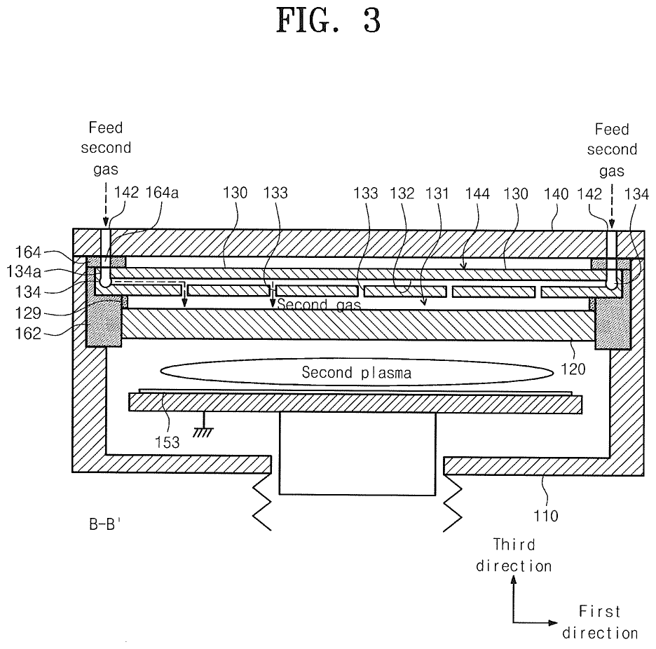

FIG. 3 is a cross-sectional view taken along line B-B′ in FIG. 1.

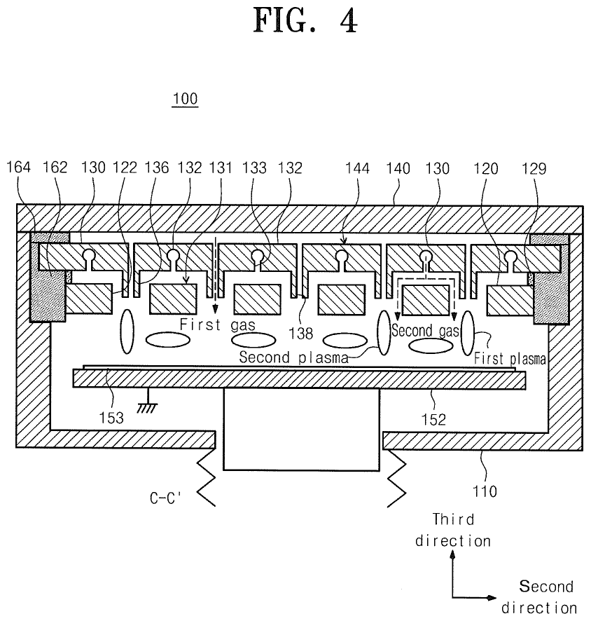

FIG. 4 is a cross-sectional view taken along line C-C′ in FIG. 1.

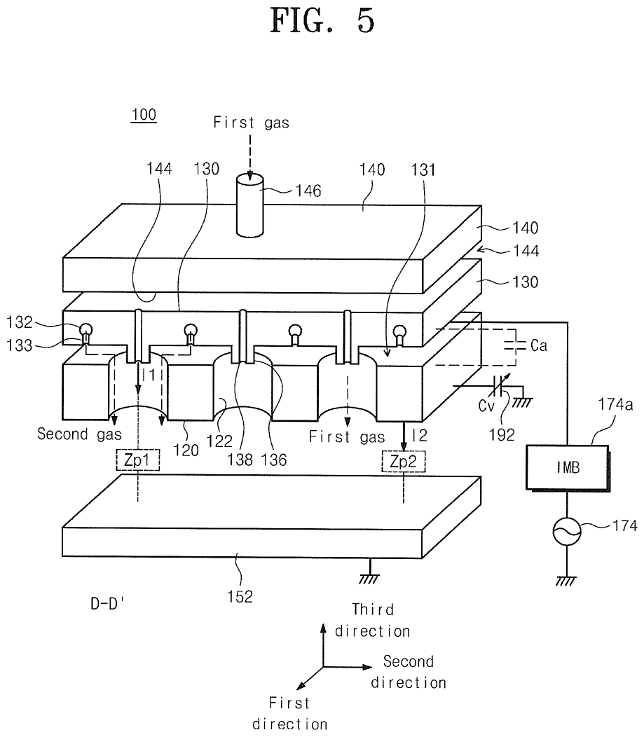

FIG. 5 is a cutaway perspective view taken along line D-D′ in FIG. 1.

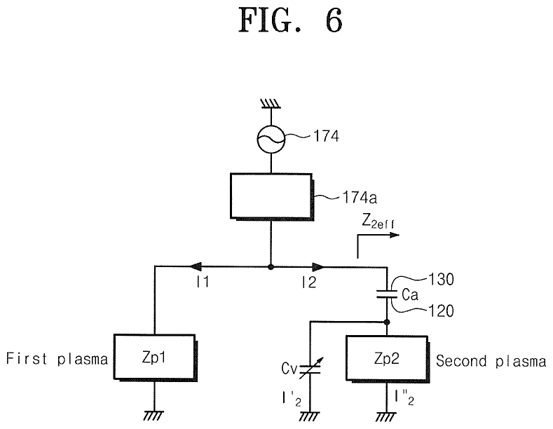

FIG. 6 is a circuit diagram illustrating the substrate processing apparatus in FIG. 1.

Referring to FIGS. 1 to 6, a substrate processing apparatus 100 according to an example embodiment may include a process chamber 110, an upper electrode 130 having a plurality of protrusion portions 136 spaced apart from an upper surface of an upper portion of the process chamber 110 to protrude downwardly, a lower electrode 120 disposed below the upper electrode 130, a substrate seating means 152, electrically grounded and disposed to face the lower electrode 120, on which a substrate is mounted, and a variable capacitor 192 connected between the lower electrode 120 and a ground or between the lower electrode 120 and an RF power supply.

A substrate processing apparatus 100 according to an example embodiment may include a process chamber 110, an upper electrode 130 disposed above the process chamber 110 and spaced apart from an upper surface of the process chamber 110, a lower electrode 120 disposed to oppose the upper electrode 130 below the upper electrode 130 at a predetermined distance from the upper electrode 130, a substrate seating means 152, electrically grounded and disposed to face the lower electrode 120 below the lower electrode 120 at a predetermined distance from the lower electrode 120, on which a substrate is mounted, and a variable capacitor 192 connected between the lower electrode 120 and the ground or between the lower electrode 120 and an output terminal of an RF power supply 174.

The upper electrode 130 includes a plurality of protrusion portions 136 protruding in a direction of the lower electrode 120. The protrusion portions 136 are aligned with openings 122 formed in the lower electrode 120, respectively. A first gas is supplied to the substrate seating means 152 through a first nozzle 138 formed through the protrusion portion 136. A second gas may be injected through a second nozzle 133 formed in a lower surface of the upper electrode 130, and may be supplied to the substrate seating means 152 through a flow path between the upper electrode 130 and the lower electrode 120 and the opening 122. The upper electrode 130 is connected to the RF power supply 174. A portion of RF power, supplied by the RF power supply 174, generates first plasma between the protrusion portion 136 and the grounded substrate seating means 152. The rest of the RF power, supplied by the RF power supply 174, is transferred to the lower electrode 120 through a parasitic capacitor between the upper electrode 130 and the lower electrode 120, and generates second plasma between the lower electrode 120 and the substrate seating means 152.

The substrate processing apparatus 100 may perform an atomic layer deposition process using the first gas, supplied to the first nozzle 138, and the second gas supplied to the second nozzle 133. The substrate processing apparatus 100 may receive help of plasma for the atomic layer deposition. When a plasma technology is applied to the atomic layer deposition, reactivity of an atomic layer deposition reactive gas may be improved, a process temperature range may be increased, and a purge time may be reduced.

In plasma enhanced atomic layer deposition (PE-ALD), a purge gas may be supplied after sequentially providing precursors, purging the precursors using the purge gas, and supplying a reactive gas by plasma. Due to the supply of the reactive gas by the plasma, reactivity of the precursors may be increased to increase a film deposition rate and to decrease a temperature of the substrate.

The substrate processing apparatus 100 according to an example embodiment may simultaneously generates first plasma and second plasma, and may adjusts a power ratio of the first plasma and the second plasma to simultaneously achieve a high thin-film growth rate and a high-quality thin film.

The variable capacitor 192 may be connected between the lower electrode 120 and the ground. Capacitance of the variable capacitor 192 is Cv. The lower electrode 120 may receive RF power through capacitance Ca of a parasitic capacitor between the upper electrode 130 and the lower electrode 120.

The first plasma may be generated between the protrusion portion 136 of the upper electrode 130 and the substrate seating means 152. The second plasma may be generated between the lower electrode 120 and the substrate seating means 152. First plasma impedance Zp1 of the first plasma may be represented by an equivalent circuit of first plasma resistance Rp1 and first plasma reactance Xp1. Second plasma impedance Zp2 of the second plasma may be represented by an equivalent circuit of second plasma resistance Rp2 and second plasma reactance Xp2.

Accordingly, an output terminal of an impedance matching network 174a (IMB) may be indicated by parallel connection of the first plasma impedance Zp1 and effective impedance Z_{2eff}. The effective impedance Z_{2eff} may include a variable capacitor 192, connected in parallel to the second plasma impedance Zp2, and a parasitic capacitor connected in series to the second plasma impedance Zp2 and variable capacitor 192 connected in parallel to each other.

To simply check power division, it is assumed that the first plasma impedance Zp1 of the first plasma is first capacitance C1. In addition, it is assumed that the second plasma impedance Zp2 of the second plasma is the second capacitance C2. First current flows to the first plasma impedance Zp1, and second current flows to the parasitic capacitor.

A ratio of the first current to the second current is given as follows.

$${Z}_{p 1} = \frac{1}{{jωC}_{1}} {Z}_{p 2} = \frac{1}{{jωC}_{2}} \\ {Z}_{2 eff} = \frac{1}{{jωC}_{a}} + \frac{1}{jω [ {C}_{v} + {C}_{2} ]} \\ If {C}_{V} ⪢ {C}_{a} , {Z}_{2 eff} \approx \frac{1}{{jωC}_{a}} , \frac{{I}_{1}}{{I}_{2}} = \frac{{Z}_{2 eff}}{{Z}_{p 1}} \approx \frac{{C}_{1}}{{C}_{a}} \\ If {C}_{V} \to 0 , {Z}_{2 eff} \approx \frac{1}{{jωC}_{a}} + \frac{1}{{jωC}_{2}} , \frac{{I}_{1}}{{I}_{2}} = \frac{{Z}_{2 eff}}{{Z}_{p 1}} \approx \frac{{C}_{1} [ {C}_{a} + {C}_{2} ]}{{C}_{a} {C}_{2}} \qquad Equation 1$$

where ω is an angular frequency of the RF power supply 174, Zp1 is the first plasma impedance of the first plasma, Zp2 is the second plasma impedance of the second plasma, Ca is capacitance of the parasitic capacitor between the upper electrode and the lower electrode, and Cv is capacitance of the variable capacitor 192 connected in parallel to the second plasma.

When the capacitance Cv of the variable capacitor 192 varies, a ratio of first current I1, flowing through the first plasma, to second current I2, flowing through the effective impedance Z_{2eff}, may be adjusted. The second current I2 is divided into current I′2, flowing through the variable capacitor 192, and current I″2 flowing through the second plasma impedance. For example, the current I″2 flowing through the second plasma impedance is controlled depending on the capacitance Cv of the variable capacitor 192.

Accordingly, the variable capacitor 192 may adjust a ratio of RF power generating the first plasma and the second plasma. The first plasma may discharge the first gas or the second gas at high plasma density, and the second plasma may discharge the first gas or the second gas at low plasma density. The density of the first plasma, generated in the opening 122, may be higher than that of the second plasma generated below the lower electrode 120. For example, the first plasma may sufficiently dissociate the first gas or the second gas in the opening 122, and the second plasma may activate the first gas or the second gas while suppressing damage to film quality due to low plasma density. As a result, a thin-film deposition rate and film quality may be improved.

As the capacitance Cv of the variable capacitor 192 varies, the first current I1 flowing through the first plasma impedance Zp1 and the current I″2 flowing through the second plasma impedance Zp2 may vary. A ratio of the first RF power, generating the first plasma, to the second RF power, generating the second plasma, may be selected according to a thin film to be deposited.

The process chamber 110, as a metal chamber, may be a cylindrical chamber or a cuboid chamber. A lid 140 of the process chamber 110 may cover an open upper surface of the process chamber 110. The process chamber 110 may be exhausted to be in a vacuum state by an exhaust unit. The process chamber 110 may be electrically grounded.

The lid 140 may be disposed above the upper electrode 130 to be spaced apart therefrom, and a gas buffer space 144 may be provided between a lower surface of the lid 140 and an upper surface of the upper electrode 130. The lid 140 may have a plate shape, may be formed of a conductive material, and may be grounded. The gas buffer space 144 may have a height of several millimeters or less to prevent generation of parasitic plasma. The gas buffer space 144 may receive a first gas from an external entity through a gas supply line 146. The gas buffer space 144 may supply the first gas to the opening 122 of the lower electrode through a first nozzle 138 penetrating through the protrusion portions 136.

The upper electrode 130 may be disposed to be spaced apart from the lower portion of the lid 140. The upper electrode 130 may receive RF power from the RF power supply 174 through the impedance matching network 174a. The upper electrode 130 may be a plate-shaped conductive material. The upper electrode 130 may include a plurality of protrusion portions 136 protruding from a lower surface thereof. The protrusion portions 136 may be arranged in a matrix form. The first nozzle 138 may be formed by penetrating through the protrusion portion 136 or continuously penetrating through the protrusion portion 136 and the upper electrode 130. The first nozzle 138 may inject the first gas.

The upper electrode 130 may include a plurality of first-direction flow paths 132, extending in parallel in a first direction, and a pair of second-direction flow paths extending in a second direction, perpendicular to the first direction, and respectively connecting both ends of the first-direction flow paths 132. The second nozzles 133 may be connected to the first-direction flow path 132. The second nozzles 133 may be arranged on a lower surface of the upper electrode in a matrix form at regular intervals. The first nozzles 138 and the openings 122 may be disposed between adjacent first-direction flow paths 132 in the first direction at regular intervals. The pair of second-direction flow paths 134 may extend on both ends of the first-direction flow paths 132 in the second direction to supply a second gas to the first-direction flow paths 132.

The lower electrode 120 may be a plate-shaped conductive material. A gap between the lower electrode 120 and the upper electrode 130 may be several millimeters or less to prevent generation of parasitic plasma. A space 131 between the lower electrode 120 and the upper electrode 130 may form a flow path such that the second gas, injected through the second nozzle 133, may be discharged through the openings 122.

The lower electrode 120 may receive a portion of the RF power, supplied to the upper electrode 130, through capacitive coupling of the parasitic capacitor. The lower electrode 120 may include a plurality of openings 122 arranged in a matrix form. The substrate seating means 152 and the grounded lower electrode 120 may generate second plasma. The lower electrode 120 may be electrically connected to the variable capacitor 192.

The substrate seating means 152 may be electrically grounded and may have a plate shape. The substrate seating means 152 may mount the substrate 153 on an upper surface thereof. The substrate seating means 152 may support the substrate 153 and may heat or cool the substrate 153 at a constant temperature.

The RF power supply 174 may have a frequency of several MHz to several hundreds of MHz, and may supply RF power to the upper electrode 130 through the impedance matching network 174a. The upper electrode 130 may receive the RF power in a plurality of points to suppress a standing wave effect.

The insulating spacer 129 may be disposed on an edge of an upper surface of the lower electrode 120. The insulating spacer 129 may electrically insulate the upper electrode 130 and the lower electrode 120 from each other, and may provide a flow path through which the second gas flows. The flow path may be a space in which the second gas, injected by the second nozzles 133, is diffused. The insulating spacer 129 may have a thickness of several millimeters or less such that the second gas does not generate parasitic plasma in the flow path.

An insulating portion 162 may be disposed to surround edges of the upper electrode 130 and the lower electrode 120. The insulating portion 162 may be coupled to a sidewall of the process chamber 110. The insulating portion 162 may be inserted into a step, formed on an upper internal wall of the process chamber 110, to be coupled the sidewall of the process chamber 110. The insulating portion 162 may support the upper electrode 130 through an auxiliary step formed in an upper portion thereof.

An auxiliary insulating spacer 164 may be disposed to cover edges of the insulating portion 162 and the upper electrode 130. The auxiliary insulating spacer 164 may provide the gas buffer space 144 between the lid 140 and the upper electrode 130. The auxiliary insulating spacer 164 may be aligned with an external surface of the insulating portion 162. The auxiliary insulating spacer 164 may be a ceramic, such as alumina, or plastic. The auxiliary insulating spacer 164 may have a thickness of several hundreds of micrometers to several millimeters to prevent generation of parasitic plasma. The gas buffer space 144 may communicate with the first nozzles 138 penetrating through the upper electrode 130 and the protrusion portion 136.

The gas supply path 142 may vertically penetrate through an edge of the lid 140 to be connected to the second-direction flow path 134. A first auxiliary hole 134a may be disposed in the edge of the upper electrode 130 to connect the gas supply path 142 and the second-direction flow path 134. A second auxiliary hole 164a may be disposed to penetrate through the auxiliary insulating spacer 164 to be aligned with the first auxiliary hole 134a. The gas supply path 142 may include a plurality of gas supply paths 142, and may be disposed in the second direction.

The RF power supply line 172 may vertically penetrate through the lid 140 between a pair of adjacent first nozzles 138, aligned in the first direction, to be electrically connected to the upper electrode 130.

The upper electrode 130 may inject the first gas to the substrate 153 through the first nozzle 138 and may inject the second gas to the flow path through the second nozzle 133. The second gas, diffused in the flow path, may be injected through the opening 122 in a direction of the substrate 153. The first gas may be a precursor gas, and the second gas may be a reactive gas. Alternatively, the first gas may be a reactive gas, and the second gas may be a precursor gas. The precursor gas may be tri-methyl aluminum (TMA), TiCl4, HfCl4, or SiH4. The reactive gas may include at least one of H2, N2, O2, NH3, Ar, and He.

The plasma enhanced atomic layer deposition (PE-ALD) process may include a first step, a second step, a third step, and a fourth step. In the first step, the upper electrode 130 injects a first gas (for example, a precursor gas) through the first nozzle 138. In the second step, a purge gas (for example, an argon gas) is injected through the first nozzle 138 to remove an excess precursor gas on a substrate. In the third step, RF power is supplied to the upper electrode 130, while supplying a second gas (for example, a reactive gas) through the second nozzle 133, to generate first plasma between the protrusion portion 136 and the substrate seating means 152 and to generate second plasma between the lower electrode 120 and the substrate seating means 152. The first plasma may sufficiently dissociate the second gas in the opening 122. The second plasma may activate the second gas between the lower electrode 120 and the substrate seating means 152. In the fourth step, the purge gas (for example, the argon gas) is injected through the second nozzle 133 to remove a second excess gas. The above-described first to fourth steps may be repeated.

A method of operating a substrate processing apparatus according to an example embodiment may include supplying a first gas to the substrate seating means 152 through a first nozzle 138 formed in the protrusion portion 136, supplying a second gas to the substrate seating means 152 through a second nozzle 133, formed in the lower surface of the lower electrode 120, through the opening 122, supplying RF power to the upper electrode 130 by the RF power supply 174 to generate first plasma between the protrusion portion 136 and the substrate seating means 152, and dividing the RF power, supplied to the upper electrode 130, to the lower electrode 120 to generate second plasma between the lower electrode 120 and the substrate seating means 152. The first plasma and the second plasma may be simultaneously generated. The first plasma may have higher density than the second plasma.

For atomic layer deposition (ALD), the method may further include supplying a purge gas to the substrate seating means 152 through the first nozzle 138 formed in the protrusion portion 136 after supplying the first gas to the substrate seating means 152 through the first nozzle 138.

In the method, for chemical vapor deposition (CVD), the first gas and the second gas may be simultaneously supplied and the first plasma and the second plasma may be simultaneously formed.

In the method, capacitance of the variable capacitor may be varied to adjust characteristics of the first plasma and the second plasma.

The substrate processing apparatus according to an example embodiment may be applied to a chemical vapor deposition (CVD) process. The first nozzles 138 may inject a first gas such as SiH4 and, at the same time, the second nozzles 133 may inject a dilution gas such as hydrogen, nitrogen, or ammonia. The first plasma may sufficiently dissociate the first gas and the second gas, and the second plasma may activate the first gas and the second gas.

The substrate processing apparatus according to an example embodiment may perform an atomic layer deposition (ALD) process of an organic layer or an inorganic layer to improve moisture permeability characteristics in an encapsulation process of a large-area display.

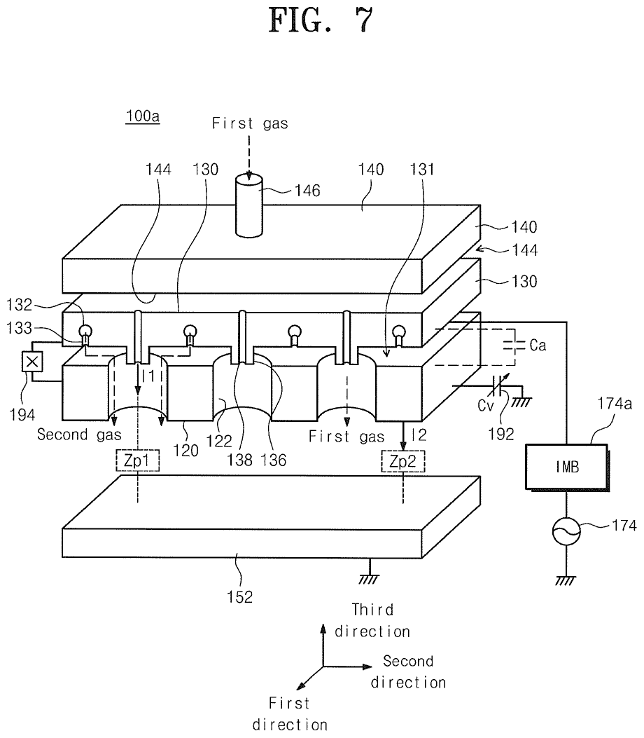

FIG. 7 is a conceptual diagram illustrating a substrate processing apparatus according to another example embodiment of the present disclosure.

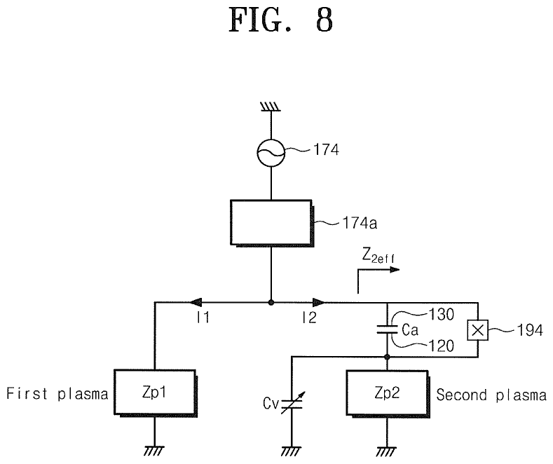

FIG. 8 is a circuit diagram illustrating the substrate processing apparatus in FIG. 7.

Referring to FIGS. 7 and 8, a substrate processing apparatus 100a may further include a reactive element 194 connected between an upper electrode 130 and a lower electrode 120. The reactive element 194 may have reactance X. The reactive element 194 may be a fixed capacitor. The reactive element 194 may be connected to a parasitic capacitor in parallel. The reactive element 194 may efficiently transfer RF power to the lower electrode 120. The reactive element 194 may improve linearity of a power division ratio depending on capacitance Cv of a variable capacitor 192.

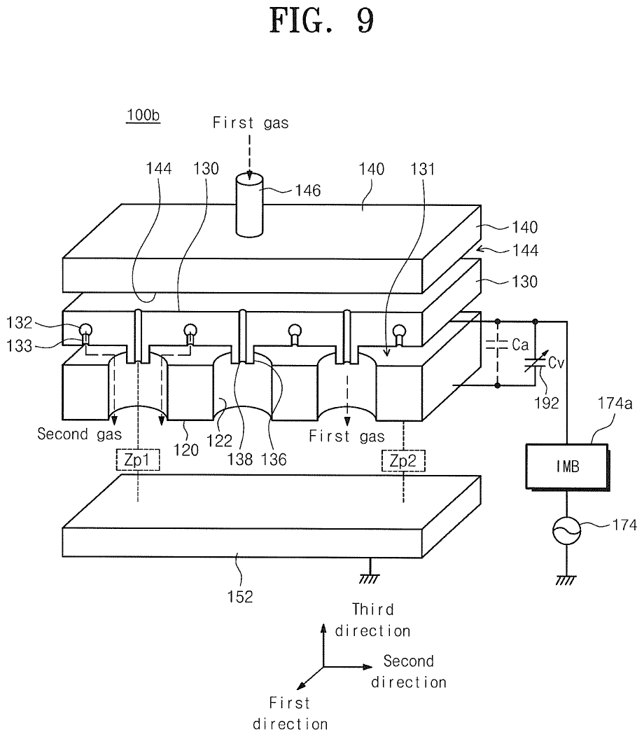

FIG. 9 is a cutaway perspective view illustrating a substrate processing apparatus according to another example embodiment of the present disclosure.

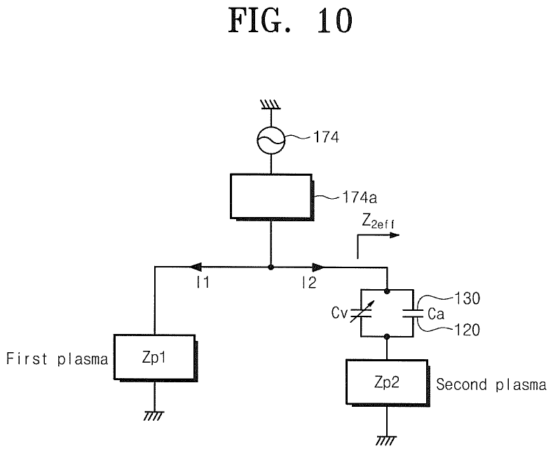

FIG. 10 is a circuit diagram illustrating the substrate processing apparatus in FIG. 9.

Referring to FIGS. 9 and 10, a substrate processing apparatus 100b may include a variable capacitor 192 connected between a lower electrode 120 and an output terminal of an RF power supply 174. Specifically, an output terminal of an impedance matching network 174a may branch off to be connected to the upper electrode 130, and may be connected to the lower electrode 120 through the variable capacitor 192. The upper electrode 130 may be connected to the lower electrode 120 through the variable capacitor 192 and the parasitic capacitor.

When capacitance Cv of the variable capacitor 192 is adjusted, a ratio of first RF power, supplied to first plasma generated between a protrusion portion 136 of the upper electrode 130 and the substrate seating means 152, to second RF power, supplied to second plasma generated between the lower electrode 120 and the substrate seating means 152, may be adjusted. A parasitic capacitor between the upper electrode 130 and the lower electrode 120 may be connected in parallel to the variable capacitor 192. The second plasma impedance Zp2 may be connected in series to the parasitic capacitor and variable capacitor 192 connected to each other in parallel.

To simply check power division, it is assumed that first plasma impedance Zp1 of the first plasma is first capacitance C1 and second plasma impedance Zp2 of the second plasma is second capacitance C2. A ratio of first current to second current is given, as follows.

$${Z}_{p 1} = \frac{1}{{jωC}_{1}} {Z}_{p 2} = \frac{1}{{jωC}_{2}} \\ {Z}_{2 eff} = \frac{1}{{jωC}_{2}} + \frac{1}{jω [ {C}_{v} + {C}_{a} ]} \\ If {C}_{V} ⪢ {C}_{a} , {Z}_{2 eff} \approx \frac{1}{{jωC}_{v}} + \frac{1}{{jωC}_{2}} , \frac{{I}_{1}}{{I}_{2}} = \frac{{Z}_{2 eff}}{{Z}_{p 1}} \approx \frac{{C}_{1}}{{C}_{2}} \frac{[ {C}_{2} + {C}_{v} ]}{{C}_{v}} \\ If {C}_{V} \to 0 , {Z}_{2 eff} \approx \frac{1}{{jωC}_{2}} + \frac{1}{{jωC}_{a}} , \frac{{I}_{1}}{{I}_{2}} = \frac{{Z}_{2 eff}}{{Z}_{p 1}} \approx \frac{{C}_{1}}{{C}_{2}} \frac{[ {C}_{2} + {C}_{a} ]}{{C}_{a}} \qquad Equation 2$$

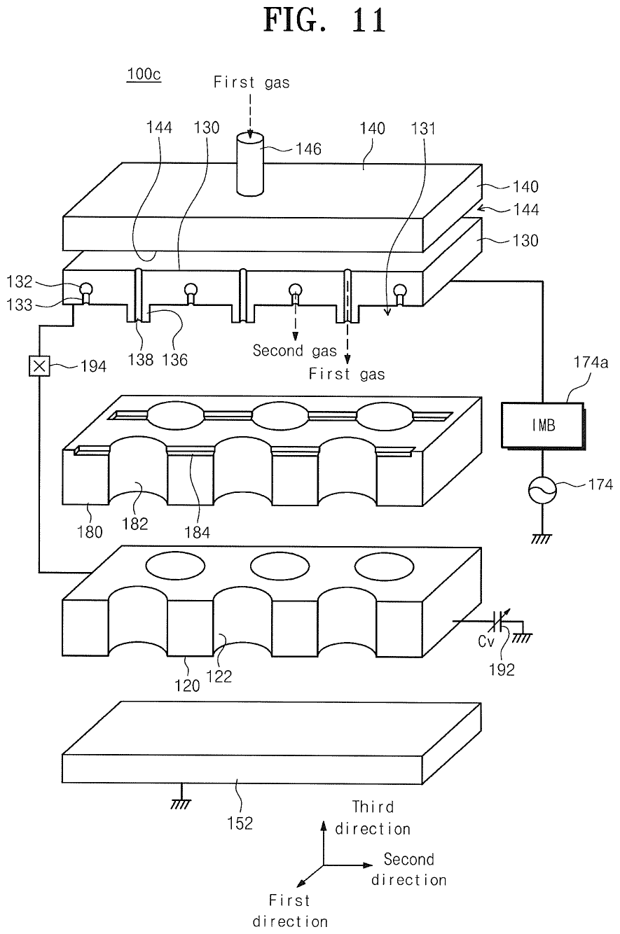

FIG. 11 is an exploded cutaway perspective view illustrating a substrate processing apparatus according to another example embodiment of the present disclosure.

Referring to FIG. 11, a substrate processing apparatus 100c may include a flow path insulating plate 180. The flow path insulating plate 180 may be disposed between the upper electrode 130 and the lower electrode 120. The flow path insulating plate 180 may be an insulator. The flow path insulating plate 180 may have auxiliary openings 182 aligned with the openings 122. The auxiliary openings 182 may penetrate through the flow path insulating plate 180. The flow path insulating plate 180 may have a trench 184 connecting the second nozzle 133 and the auxiliary opening 182. The trench 184 may extend from an upper surface of the flow path insulating plate 180 in a second direction. The flow path insulating plate 180 may form a flow path while suppressing parasitic discharge.

A reactive element 194 may be additionally disposed between the upper electrode 130 and the lower electrode 120 to transfer RF power, supplied from the upper electrode 130, to the lower electrode 120.

The reactive element 194 may be a fixed capacitor. The flow path insulating plate 180 may provide a flow path of a second gas while suppressing parasitic discharge.

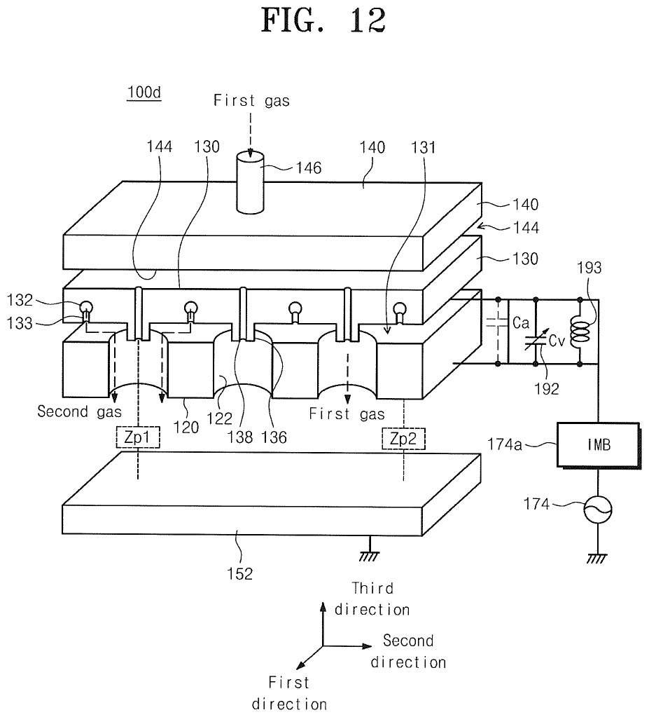

FIG. 12 is a cutaway perspective view illustrating a substrate processing apparatus according to another example embodiment of the present disclosure.

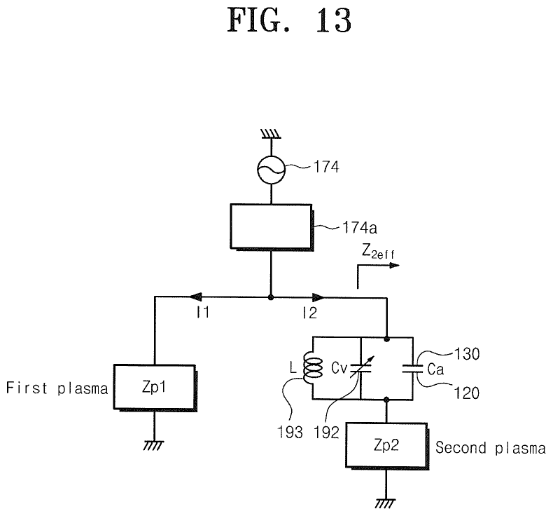

FIG. 13 is a circuit diagram of the substrate processing apparatus in FIG. 12.

Referring to FIGS. 12 and 13, a substrate processing apparatus 100d may include a variable capacitor 192 and a fixed inductor 193 connected between an upper electrode 130 and a lower electrode 120. The fixed inductor 193 may have inductance L. Capacitance Ca of a parasitic capacitor, capacitance Cv of the variable capacitor 192, and the inductance L of the fixed inductor 193 may constitute a parallel resonance circuit. When an RF power supply operates at a resonant frequency through adjustment of the capacitance Cv of the variable capacitor 192, impedance of the resonant circuit may be indefinitely increased, and thus, power of the RF power supply may mainly selectively generate only first plasma. Meanwhile, when the RF power supply operates at a frequency, deviating from the resonance frequency, through adjustment of the capacitance Cv of the variable capacitor 192, RF power may be divided between a lower electrode and a substrate seating means to simultaneously generate first plasma and second plasma.

Returning to FIG. 5, the substrate processing apparatus 100 according to an example embodiment may include a process chamber 110, an upper electrode 130 disposed inside the process chamber 110 and having a nozzle protruding in a lower length direction; a lower electrode 120 disposed below the upper electrode 130, and a substrate seating means 152, disposed to face the lower electrode 120, on which a substrate is mounted. The lower electrode 120 is electrically floated.

That is, in FIG. 5, the variable capacitor 192 may be removed. Accordingly, the lower electrode 120 may receive RF power from the upper electrode 130 through capacitive coupling to generate second plasma between the lower electrode 120 and the substrate seating means 152. In addition, a protrusion portion of the upper electrode 130 may generate first plasma between the upper electrode 130 and the substrate seating means 152 through an opening of the lower electrode 120. A voltage division model may cause a voltage drop between the lower electrode 120 and the substrate seating means 152 to be less than a voltage drop between the upper electrode 130 and the substrate seating means 152. As a result, characteristics of the second plasma may be different from characteristics of the first plasma.

As described above, a plasma substrate processing apparatus according to an example embodiment may change characteristics of a thin film by adjusting a ratio of RF power applied to first plasma, generated between an upper electrode having a protrusion portion and a substrate seating means, to RF power applied to second plasma, generated between a lower electrode having an opening aligned with the protrusion portion and the substrate seating means.

In addition, a plasma substrate processing apparatus according to an example embodiment may perform atomic layer deposition (ALD) by separately injecting two types of gases through different paths and respectively generating first plasma and second plasma in different regions using one of the two types of gases.

In addition, a plasma substrate processing apparatus according to an example embodiment may improve large-area film quality and film-forming characteristics by generating first plasma and second plasma in difference spaces to apply a difference in dissociation rate.

While example embodiments have been shown and described above, it will be apparent to those skilled in the art that modifications and variations could be made without departing from the scope of the present inventive concept as defined by the appended claims.

What is claimed is:

1. A substrate processing apparatus comprising:
a process chamber;
an upper electrode having a plurality of protrusion portions spaced apart from an upper surface of an upper portion of the process chamber to protrude downwardly;
a lower electrode disposed below the upper electrode;
a substrate seating means, electrically grounded and disposed to face the lower electrode, on which a substrate is mounted; and
a variable capacitor connected between the lower electrode and a ground or between the lower electrode and an RF power supply.

2. The substrate processing apparatus as set forth in claim 1, wherein the upper electrode is connected to the RF power supply to generate a first plasma between the protrusion portions and the substrate seating means, and
RF power of the RF power supply generates a second plasma between the lower electrode and the substrate seating means.

3. The substrate processing apparatus as set forth in claim 1, wherein a first gas is supplied to the substrate seating means through a first nozzle formed in the protrusion portions, and
a second gas is supplied to the substrate seating means through a second nozzle, formed in a lower surface of the upper electrode, through an opening.

4. The substrate processing apparatus as set forth in claim 2, wherein the protrusion portions and a plurality of first nozzles are periodically disposed in a matrix form, and
a plurality of second nozzles are spaced apart from the first nozzles to be periodically disposed in a matrix form.

5. The substrate processing apparatus as set forth in claim 1, further comprising:
a reactive element connected between the upper electrode and the lower electrode.

6. The substrate processing apparatus as set forth in claim 1, wherein an output terminal of the RF power supply is connected to the upper electrode,
RF power of the RF power supply is transferred to the lower electrode through a parasitic capacitor between the upper electrode and the lower electrode, and
the variable capacitor is connected between the lower electrode and a ground.

7. The substrate processing apparatus as set forth in claim 1, wherein an output terminal of the RF power supply is connected to the upper electrode,
the variable capacitor is connected between the upper electrode and the lower electrode, and
RF power of the RF power supply is transferred to the lower electrode through the variable capacitor and a parasitic capacitor between the upper electrode and the lower electrode.

8. The substrate processing apparatus as set forth in claim 7, further comprising:
a fixed inductor connected between the upper electrode and the lower electrode.

9. A method of operating a substrate processing apparatus comprising an upper electrode disposed in an upper portion of a process chamber and disposed to be spaced apart from an upper surface of the process chamber, a lower electrode disposed below the upper electrode at a constant distance from the upper electrode and disposed to oppose the upper electrode, a substrate seating means, electrically ground, disposed below the lower electrode at a constant distance from the upper electrode, and disposed to face the lower electrode, on which a substrate is mounted, and a variable capacitor connected between the lower electrode and a ground or between the lower electrode and an output terminal of an RF power supply, wherein the upper electrode has a plurality of protrusion portions protruding in a direction of the lower electrode, and the plurality of protrusion portions are respectively aligned with openings formed in the lower electrode, the method comprising:
supplying a first gas to the substrate seating means trough a first nozzle formed in the protrusion portions;
supplying a second gas to the substrate seating means through a second nozzle, formed in a lower surface of the lower electrode, through the openings;
supplying RF power to the upper electrode by the RF power supply to generate first plasma between the protrusion portions and the substrate seating means; and
dividing the RF power, supplied to the upper electrode, to the lower electrode by the RF power supply to generate second plasma between the lower electrode and the substrate seating means.

10. The method as set forth in claim 9, wherein the first plasma and the second plasma are simultaneously generated.

11. The method as set forth in claim 10, further comprising:
changing capacitance of the variable capacitor.

12. A substrate processing apparatus comprising:
a process chamber;
an upper electrode disposed inside the process chamber and having a nozzle protruding in a lower length direction;
a lower electrode disposed below the upper electrode; and
a substrate seating means, disposed to face the lower electrode, on which a substrate is mounted,
wherein the lower electrode is electrically floated.
